(19) United States
(12) Patent Application Publication
(10) Pub. No.: US 2008/0157334 A1
(43) Pub. Date: Jul. 3, 2008

(54) Memory module for improving impact resistance

(75) Inventor: Wen-Jeng Fan, Hukou Shiang (TW)

Correspondence Address: TROXELL LAW OFFICE PLLC, 5205 LEESBURG PIKE SUITE 1404, FALLS CHURCH, VA, 22041, US

(73) Assignee: POWERTECH TECHNOLOGY INC.

(21) Appl. No.: 11/647,376

(22) Filed: Dec. 29, 2006

(51) Int. Cl. H01L 23/48

(52) U.S. Cl. 257/690

(57) ABSTRACT

A memory module for improving impact resistance mainly comprises a multi-layer PWB (Printed Wiring Board) and a plurality of memory packages. The multi-layer PWB is rectangular and has two longer sides and two shorter sides, wherein a plurality of gold fingers are disposed along one of the longer sides, at least an arc notch and a plurality of first stress-absorbing slots are formed at the two shorter sides respectively. Preferably, plural second stress-absorbing slots are formed at another longer side far away from the gold fingers. The impact stress due to accidental drop may be absorbed by the first stress-absorbing slots or/and the second stress-absorbing slots to prevent the product from damaging.

### FIELD OF THE INVENTION

The present invention relates to a memory module including random access memory integrated circuits, more particularly to a memory module for improving impact resistance.

### BACKGROUND OF THE INVENTION

Within electronic products such as computer mainframe and notebook micro computer, memory module that typically is a critical part can be repetitively plugged into the memory socket of mother board to serve operations of computer system. Sometimes there is possibility to drop the memory module accidentally during carrying, conveying or replacing process, and however, the memory modules of the present time are typically subject to damage due to bad impact resistance.

Referring to FIG. 1, a known memory module 100 comprises a multi-layer PWB 110 (Printed Wiring Board) and a plurality of memory packages 120. The multi-layer PWB 110 has two longer sides 111 and two shorter sides 112. The memory packages 120 are mounted onto the multi-layer PWB 110. Plural gold fingers 113 are formed on one of the longer sides 111 of the multi-layer PWB 110 for electrical connection. At least an arc notch 114 is formed at each of the two shorter sides respectively for alignment when plugging into a memory socket. In order to confirm impact resistance of the known memory module 100, a drop test is performed. Referring to FIG. 2, the known memory module 100 is provided and placed at a predetermined height H, such as from 50 cm to 100 cm, then falls like a free falling body from diverse angles to impact cement ground 10. Finally, the fallen memory module 100 will be checked if it normally functions. Unfortunately, the memory modules 100 of the present day have been confirmed that they are highly vulnerable to damage for shock hard to pass impact test and it has been found the joint interface between the PWB 110 and the memory packages 120 is often broken resulting in electrical disconnection.

Referring to FIG. 3, the memory packages 120 may generally be BGA (Ball Grid Array) packages and has a plurality of solder balls 121 that are mounted onto the ball pads 122 of the substrate and are exposed on a solder resist layer 123. Moreover, a plurality of ball-mounting pads 115 are disposed on the multi-layer PWB 110 and exposed from the solder resist layer 116 to serve mounting the solder balls 121. While falling as a free falling body to impact, a stress from the PWB 110 is conducted to the memory packages 120 to cause cracks 124 or/and 125 at mounting interfaces between the solder balls 121 and the ball pads 122 or/and at mounting interfaces between the solder balls 121 and the ball-mounting pads 115, which enables the entire memory module product not to normally work.

### SUMMARY OF THE INVENTION

The primary object of the present invention is to provide a memory module for improving impact resistance, which can release impact force by utilizing stress-absorbing slots to prevent electrical disconnection when memory module falls to result in product failure.

One aspect of the present invention provides a memory module that mainly comprises a multi-layer PWB and a plurality of memory packages. The multi-layer PWB is rectangular having two longer sides and two shorter sides, the PWB has a plurality of gold fingers disposed along one of the longer sides, at least an arc notch at each shorter side and a plurality of stress-absorbing slots extending along and adjacent to the two shorter sides. The memory packages are mounted onto the multi-layer PWB.

With respect to the memory module mentioned above, the memory packages may be BGA package having a plurality of solder balls.

With respect to the memory module mentioned above, the multi-layer PWB may have a plurality of ball-mounting pads to mount the solder balls.

With respect to the memory module mentioned above, the ball-mounting pads may be NSMD pads (Non-Solder Mask Defined pad).

With respect to the memory module mentioned above, the stress-absorbing slots may be strip-like shapes.

With respect to the memory module mentioned above, the stress-absorbing slots at a same shorter side may be arranged in line.

With respect to the memory module mentioned above, it further forms a plurality of stress-absorbing slots at another longer side far away from the gold fingers on the multi-layer PWB.

With respect to the memory module mentioned above, the stress-absorbing slots located at the longer side may be arranged in line.

With respect to the memory module mentioned above, the memory module may be DIMM (Dual In-Line Memory Module).

With respect to the memory module mentioned above, some of the memory packages may be mounted onto another surface of the multi-layer PWB.

With respect to the memory module mentioned above, there may have spaces between the stress-absorbing slots and the adjacent shorter sides and the PWB has a plurality of elastic integral bars formed therebetween.

### DESCRIPTION OF THE DRAWINGS

FIG. 1 is a plan view of a known memory module.

FIG. 2 is a diagram illustrating drop test that the known memory module falls from a height and in diverse angles.

FIG. 3 is a partial cross-sectional view illustrating broken place of solder ball of the known memory module after drop test.

FIG. 4 is a plan view of a memory module in accordance with the first embodiment of the present invention.

FIG. 5 is a partial cross-sectional view of a memory package of the memory module in accordance with the first embodiment of the present invention.

FIG. 6 is a plan view of another memory module in accordance with the second embodiment of the present invention.

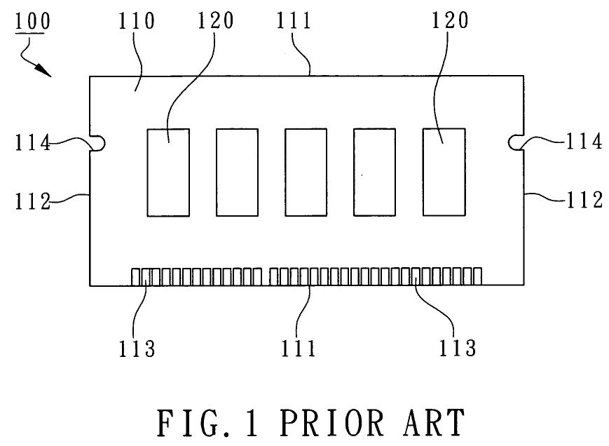

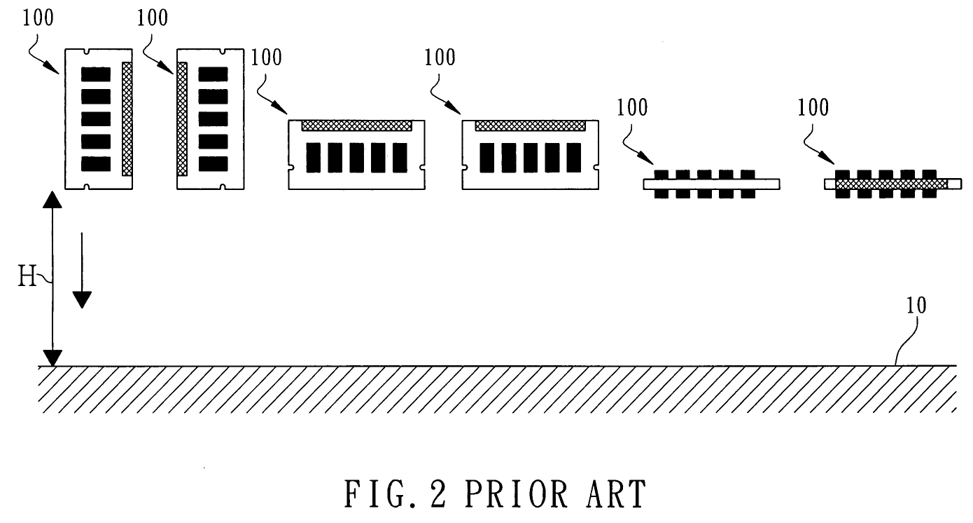

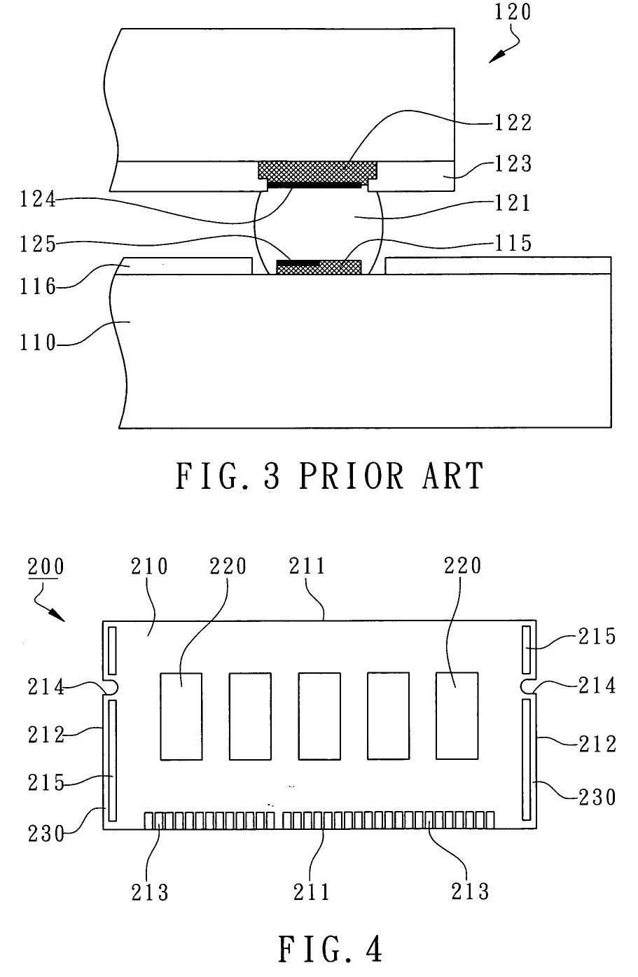

### DETAILED DESCRIPTION OF THE INVENTION

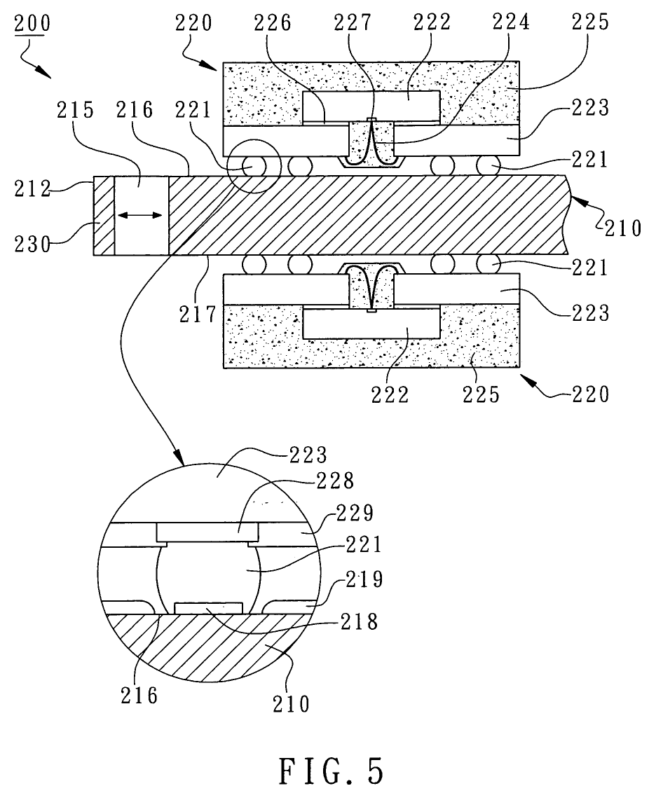

Referring to FIGS. 4 and 5, a memory module 200 for improving impact resistance is disclosed in accordance with the first embodiment of the present invention, which mainly comprises a multi-layer PWB 210 and a plurality of memory packages 220, and further has adequate amount of passive components such as capacitors, resistors (not showed in the drawings). The multi-layer PWB 210 is a rigid substrate including multi-layer traces and multi-layer dielectric core. The multi-layer PWB 210 is rectangular in shape, having two longer sides 211 and two shorter sides 212, wherein the PWB 210 has a plurality of gold fingers 213 at one of the longer sides for electrical connection when the memory module is plugged into a memory socket (not showed in the drawings) of the mother board in computer or notebook micro computer. The PWB 210 further has at least an arc notch 214 at each of the two shorter sides 212 respectively and a plurality of stress-absorbing slots 215 formed extending along and adjacent to the two shorter sides 212 respectively. The arc notches 214 can be fastened with two retainers located at two sides of memory socket to allow the memory module 200 to be fixed with the corresponding memory socket without separation. The stress-absorbing slots may be strip shape or other shapes capable of releasing impact. Besides, the multi-layer PWB 210 has an upper surface 216 and a lower surface 217. In this embodiment, the memory module 200 may be applied for SO-DIMM (Small Outline Dual In-line Memory Module) for application of notebook micro computers. There are a plurality of double-sided and independent gold fingers 213 formed along a same side of the upper surface 216 and the lower surface 217 respectively.

The memory packages 220 are mounted onto single or dual surface(s) of the multi-layer PWB 210, such as on the upper surface 216 or the lower surface 217 or both the upper and lower surfaces of the multi-layer PWB 210. FIG. 5 illustrates that some of the memory packages 220 are mounted onto the lower surface 217 of the multi-layer PWB 210 in addition to the upper surface 216. The memory packages 220 may be BGA packages including a plurality of the solder balls 221 in this embodiment. The memory packages 220 may be fine pitch BGA or window BGA packages and each seals a memory chip 222 therein such as DRAM IC. Each of the memory packages 220 may further comprise a substrate 223 serving to transmit electrical signal, a plurality of bonding wires 224 serving as electrical interconnection and an encapsulant 225 with electrical insulation. The chip 222 is attached onto the substrate 223 with a layer of chip-bonding material 226 but the bonding pads 227 of the chip 222 cannot be covered by the substrate 223. The chip 222 is electrically connected with the substrate 223 by the bonding wires 224 and the encapsulant 225 seals the chip 222 and the bonding wires 224. The solder balls 221 are mounted onto the ball pads 228 on another surface of the substrate 223 and the ball pads 228 expose on the solder resist layer 229 on a same surface of the substrate 223. The ball pads 228 may generally be SMD pads (Solder Mask Defined pad) or NSMD pads (Non-Solder Mask Defined pad). “SMD pads” means that perimeters of the ball pads 228 are covered by the solder resist layer 229. As SMD pads in round shape, the openings of the solder resist layer 229 are smaller than the ball pads 228 in diameter. Comparatively, “NSMD pads” means that perimeters of the ball pads 228 are not covered by the solder resist layer 229. As NSMD pads, the openings of the solder resist layer 229 are larger than the ball pads 228 in diameter.

Referring to FIG. 5 again, a plurality of ball-mounting pads 218 can be disposed on the multi-layer PWB 210 for mounting the solder balls 221 and it is desirable that the ball-mounting pads 218 are NSMD pads, which means the outside walls of the ball-mounting pads 218 are not covered and defined by the solder resist layer 219 of the multi-layer PWB 210 thereby improving mounting strength to the corresponding solder balls 221 and lowering the occurring possibility of crack at the mounting interface between the ball-mounting pads 218 and the solder balls 221. However, it is unlimited that the ball-mounting pads 218 may also be SMD pads.

More specifically, the memory module 200 has impact resistance because it utilizes the stress-absorbing slots 215 formed at the laterals of the multi-layer PWB 210 to create a plurality of elastic impact-absorbing bars 230 integrally joined with the multi-layer PWB 210 to release impact stress. While a shock test is performed, the elastic impact-absorbing bars 230 are able to shrink inward to the stress-absorbing slots 215 and elastically recover original shape immediately (with reference to the arrow in FIG. 5) to widely reduce impact stress directly conducted to the memory packages 220. Accordingly, the coupling interfaces of between the solder balls 221 and the ball pads 228 and between the solder balls 221 and the ball-mounting pads 218 are obviously improved for withstanding shock not to crack.

The stress-absorbing slots 215 at each shorter side 212 of the multi-layer PWB 210 may desirably be arranged in line to allow the corresponding formed elastic impact-absorbing bars 230 to have a unanimous width and elastically impact-absorbing space. The width of the elastic impact-absorbing bars 230 is typically about between 1.0 mm and 3.0 mm, approximately equal to the thickness of the PWB 210.

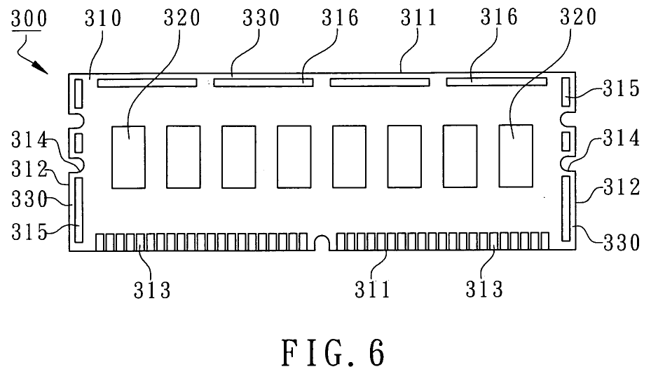

Within the second embodiment, another memory module for improving impact resistance suitable for desk-top computer, such as standards of DDR400, DDR2-533, DDR2-667 and DDR2-800 is disclosed. Referring to FIG. 6, the memory module 300 mainly comprises a multi-layer PWB 310 and a plurality of memory packages 320 mounted thereon. The memory packages 320 are mounted onto one surface or both upper and lower surfaces of the multi-layer PWB 310 and may be BGA package or other kinds of package, such as TSOP (Thin Small Outline Package).

The multi-layer PWB 310 is rectangular having two longer sides 311 and two shorter sides 312. Plural gold fingers 313 are disposed along one of the longer sides 311, and at least an arc notch 314 is formed at each of the two shorter sides 312 respectively. Additionally, the multi-layer PWB 310 further has a plurality of first stress-absorbing slots 315 in strip shape extending along and adjacent to the two shorter sides 312 respectively. It is preferable that a plurality of second stress-absorbing slots 316 are further formed to extend along and adjacent to another longer side 311 far away from the gold fingers 313 on the multi-layer PWB 310. The first stress-absorbing slots 315 located at a same shorter side 312 may be arranged in line and the second stress-absorbing slots 316 located at the longer sides 311 may also be arranged in line. Therefore, by means of spacing between the first stress-absorbing slots 315 and the corresponding shorter sides 312, a plurality of elastic impact-absorbing bars 330 integrally joined with the multi-layer PWB 310 can be formed at the perimeter of the multi-layer PWB 310 to significantly improve impact resistance so as to substantially prevent the joint interfaces between the multi-layer PWB 310 and the memory packages 320 from causing crack. The elastic impact-absorbing bars 330 have a width approximately the same as the thickness of the PCB 310.

While the present invention has been particularly illustrated and described in detail with respect to the preferred embodiments thereof, it will be clearly understood by those skilled in the art that various changed in form and details may be made without departing from the spirit and scope of the present invention.

What is claimed is:

1. A memory module comprising:
a multi-layer PWB (printed wiring board) in rectangular shape having two longer sides and two shorter sides, the PWB having a plurality of gold fingers disposed along one of the linger sides, at least an arc notch disposed at each shorter side respectively, and a plurality of first stress-absorbing slots extending along and adjacent to the two shorter sides; and
a plurality of memory packages mounted onto the PWB.

2. The memory module in accordance with claim 1, wherein the memory packages have a plurality of solder balls as BGA packages.

3. The memory module in accordance with claim 2, wherein the multi-layer PWB has a plurality of ball-mounting pads for mounting the solder balls.

4. The memory module in accordance with claim 3, wherein the ball-mounting pads are NSMD pads (Non-Solder Mask Defined pads).

5. The memory module in accordance with claim 1, wherein the first stress-absorbing slots have strip-like shape.

6. The memory module in accordance with claim 1, wherein the first stress-absorbing slots located at a same shorter side are arranged in line.

7. The memory module in accordance with claim 1, wherein a plurality of second stress-absorbing slots are formed at another longer side far away from the gold fingers on the PWB.

8. The memory module in accordance with claim 7, wherein the second stress-absorbing slots are arranged in line.

9. The memory module in accordance with claim 1, wherein the memory module is a DIMM (Dual In-Line Memory Module).

10. The memory module in accordance with claim 1, wherein the memory packages are disposed on two surfaces of the PWB.

11. The memory module in accordance with claim 1, wherein there are spaces between the first stress-absorbing slots and the adjacent shorter sides and the PWB has a plurality of elastic integral bars formed therebetween.
